(19) United States
(12) Patent Application Publication
(10) Pub. No.: US 2024/0417566 A1
(43) Pub. Date: Dec. 19, 2024

(54) Systems and Methods for Producing Carbon Solids

(71) Applicant: Soane Labs, LLC, Miami, FL (US)

(72) Inventors: David S. SOANE, Coral Gables, FL (US); Alexander V. SOANE, Coral Gables, FL (US)

(21) Appl. No.: 18/749,872

(22) Filed: Jun. 21, 2024

Related U.S. Application Data
(63) Continuation of application No. PCT/US22/53697, filed on Dec. 21, 2022.
(60) Provisional application No. 63/292,161, filed on Dec. 21, 2021.

(51) Int. Cl. C09C 1/48; B01J 6/00; C09C 1/54; C09C 1/56; C23C 16/26; C23C 16/44; C23C 16/50; C23C 16/56

(52) U.S. Cl. CPC C09C 1/485; B01J 6/008; C09C 1/54; C09C 1/56; C23C 16/26; C23C 16/4417; C23C 16/50; C23C 16/56

(57) ABSTRACT

The invention includes systems and methods for forming organized hybrid carbon solids from a hydrocarbon precursor. The hybrid carbon solid can comprise a core-shell structure in which the shell is formed from elemental carbon, and the core comprises materials that are non-elemental-carbon materials.

### RELATED APPLICATIONS

This application is a continuation of International Application No. PCT/US22/53697, which designated the United States and was filed on Dec. 21, 2022, published in English which claims the benefit of U.S. Provisional Application No. 63/292,161, filed Dec. 21, 2021. The entire teachings of the above applications are incorporated herein by reference.

### FIELD OF THE APPLICATION

This application relates to high-throughput processes for producing hybrid carbon solids.

### BACKGROUND

Solid carbon exists in different forms, such as diamond, coal, carbon black, and graphite, as well as nanoparticles, such as fullerenes, buckyballs, carbon nanobuds, nanofibers, and nanotubes. These forms, called allotropes, are different structural arrangements of elemental carbon in the same physical (i.e., solid) state. Other than diamonds, most carbon allotropes contain a high degree of aromaticity, as their carbon-carbon bonding tends to lead to fused benzene rings. Each of these allotropes has different physical properties. As used herein, the term “physical property” refers to a characteristic of a substance that can be observed and measured without changing the chemical identity of the substance. Examples include mass, density, color, temperature, volume, melting or boiling point, volume, density, and electrical and heat conductivity. The size and shape of the substance in a particular physical state is also a physical property, as it can be observed and measured without changing its chemical identity. By contrast, chemical properties are those that arise from and can be measured only by changing the chemical identity of a substance; examples include heat of combustion (ΔH_{c}, requiring complete combustion for its determination), chemical stability (tested by reacting the substance with water or air or the like to determine whether it changes its chemical composition), flammability (requiring burning the substance to assess this property), and preferred oxidation state.

Carbon black is an allotrope with a broad number of industrial applications. However, not all carbon black is created equally: carbon black can vary greatly in its structural state. Carbon black can be engineered to meet a particular industrial need, with its organization determined by its method of production and the selected process parameters.

Carbon black is produced from small spherical particles termed primary particles, having sizes ranging from 15 to 300 nm. The primary particles can have different sizes and the connectivity among the primary particles can be via fewer or more linkages (i.e., degree of branching). High interconnectivity and high surface area per unit weight are characteristics of a high structural state. The primary particles are formed into particle aggregates (approximately 85-500 nm in size) during production, with further consolidation into larger agglomerates or branched dendritic structures, with sizes on the order of 1-100 microns.

Carbon black is characterized by a very high amorphous carbon content, often >97%. More than 90% of carbon black is used as a filler for rubber production, for example tires, and technical rubber products. Because of its pigmentation properties, it is used for printing inks, varnishes, and paints.

Certain engineered structural arrangements of carbon black can provide it with electrical conductivity, allowing its use in electronics and as a filler for polymers to enhance their electroconductivity. Electroconductive carbon black is also a UV stabilizer for plastic materials because of its ability to absorb UV radiation. Further applications for electroconductive carbon black include conductive paints and coatings, fillers for anti-static rubber products (e.g., fuel hoses, conveyor belts, printing rollers, automotive belts or seals in sensitive electronic equipment), resettable fuses, heat shrinkable films and tubing, conductive inks, curable adhesives, high intensity black toner, and high contrast pigments, and the like. With the expanding demand for high performance batteries for storage and for electric vehicles, electroconductive carbon black is becoming a crucial resource. For battery applications, this material can be intimately blended with graphite granules to produce battery electrodes. The rising demand for electroconductive carbon black may require large amounts of a high performance form of carbon black: to demonstrate high conductivity, this material needs a high structural state, where the composition is ultrapure carbon (in graphitic form) and the primary particles are small (thus having high overall surface area per unit weight) and interconnected to form an extensive dendritic morphology. To meet the anticipated needs for electroconductive carbon black, the industry must produce high quality materials in large amounts at a manageable cost.

However, rapid production of high structural state carbon black has not yet been industrially achieved. Normally when the energy input for carbon black production is intense to cause rapid reaction, the resulting product is inferior in the structural state. For example, traditional arc or torch processes for carbon black formation only produce tire-filler grade carbon black, lacking the structural organization and consequent electroconductivity that makes the substance so valuable for contemporary applications.

Moreover, even filler-grade carbon black can benefit from a high structural state. For example, it is important that a tire product exhibits an optimal balance between mechanical performance, hysteresis, and flex fatigue. It is understood that the structure of carbon black has an important effect on its reinforcement properties when introduced into rubber mixtures, based on the adhesion of the carbon black to the rubber polymers. It is also understood that features of carbon black structure, in particular its surface area, impacts the wear resistance in rubber products that use carbon black: as specific surface area rises in a carbon-black/rubber composite, there is an increase in hysteresis and therefore in energy dissipation during the recurrent stress/strain conditions that the composite product (i.e., the tire) encounters, improving its wear resistance. Despite its energy dissipation benefits, highly structured carbon black typically has relatively poor dynamic properties, such as rolling resistance and wet grip. By contrast, the relatively low specific surface area of many carbon black additives decreases the composite product's hysteresis, and thus decreases its energy dissipation, while at the same time reducing rolling resistance; all of these effects are undesirable for economic and environmental reasons.

Carbon black as a filler thus demonstrates certain countervailing properties which need to be balanced in the final rubber composition. Engineering an ideally structured carbon black is currently not feasible using traditional technologies. To address these issues, other fillers are substituted for carbon black to counteract its deficiencies. For example, silica-silane fillers can be employed instead of or in addition to carbon black in rubber products, to help balance the requirements for mechanical performance, hysteresis, and flex fatigue; however, silica-silane fillers are fragile, expensive, and introduce processing complexities for tire manufacturing. In more detail, carbon black is traditionally manufactured from leftover materials from oil refining, the “bottom of an oil barrel” substances which are contaminated with impurities (i.e., hetero-atoms, such as S, N, or P). As an example, traditional carbon black from partial oxidation of pitch (a carbonaceous residue derived from petroleum, coal tar, or plants) leads to inferior products suitable for only low-grade applications such as tire making. In order to form highly structured carbon black, whether for high electrical conductivity or for other applications, the primary carbon particles that aggregate and then branch out to form carbon black must be elementally pure and they must organize themselves in a highly-structured state that possesses many intrinsic interconnections arranged in a dendritic network.

In order to ensure high elemental purity (i.e., no, or extremely low, amounts of heteroatoms in the resulting product), industry has experimented with gas feeds excited by plasma to cause solid carbon formation. Most of these efforts have centered around what is known as the torch or arc process, where intense energy input causes breakdown of a feed gas such as natural gas. However, the high energy involved in this process does not permit sufficient fine tuning to control the architecture of the resulting product; therefore, the resulting carbon black product does not exhibit a high structural state. If a less intense energy source is used to cause breakdown, such as microwave, RF, or dielectric barrier discharge (DBD), a carbon black with high structural state can be formed, but the conversion per pass through the reaction zone is extremely low, less than 1% per pass in some reports. In short, conventional approaches tend to fall into two extreme categories: high throughput (i.e., arc or torch) but poor product quality, or extremely low throughput (microwave, RF or DBD) but good quality.

There remains a need in the art, therefore, for methods for industrial production of carbon black having a high structural state, so that both high throughput and good product quality is maintained. There remains a further need to produce carbon black of high purity, having minimal heteroatom contamination. Moreover, there remains a need in the art to permit the production of carbon black with an engineered degree of structural complexity that is suitable for a specific indication.

### SUMMARY

The invention encompasses systems and methods for forming organized hybrid carbon solids from a hydrocarbon precursor. In some embodiments, the invention is directed to a system for forming organized hybrid carbon solids from a hydrocarbon precursor, wherein the hybrid carbon solid comprises a core-shell structure in which the shell is formed from elemental carbon, and the core comprises materials that are non-elemental-carbon materials, the system comprising a reaction chamber having an inlet end and an outlet end, wherein the reaction chamber comprises an initiation zone at the inlet end, a propagation zone distal to the initiation zone and in fluid communication with the initiation zone, and an annealing zone at the outlet end, distal to the propagation zone and in fluid communication with the propagation zone; wherein one or more conduits enter the initiation zone conveying a feed gas comprising the hydrocarbon precursor, and conveying a plurality of nucleation seeds, wherein the nucleation seeds comprise one or more inorganic materials; wherein the hydrocarbon precursor and the plurality of nucleation seeds are mixed before or during their entry into the initiation zone to form a feed gas mixture; wherein the feed gas mixture encounters an energy input in the initiation zone to form an activated gas stream comprising nucleation seeds and activated hydrocarbon species capable of undergoing chemical decomposition; wherein the activated gas stream enters the propagation zone and undergoes further chemical decomposition therein, forming a reactant gas stream comprising nucleation seeds and carbon solids, wherein the carbon solids deposit on the nucleation seeds to form the organized hybrid carbon solids within the reactant stream; and wherein the reactant gas stream comprising the organized hybrid carbon solids enters the annealing zone, wherein a quench gas is delivered to affect a physical or chemical property of the organized hybrid carbon solids in the reactant gas stream. In embodiments, the hydrocarbon precursor is selected from the group consisting of ethylene, ethane, and acetylene. In embodiments, the feed gas mixture comprises a second hydrocarbon precursor that is different from the hydrocarbon precursor. In embodiments, the nucleation seeds comprise one or more organic materials. In some embodiments, the inorganic materials can have magnetic or semiconductor properties. In some embodiments, the nucleation seeds comprise silicon or silica. In embodiments, the energy input forms a plasma. In embodiments, energy input is derived from a chemical reaction. The quench gas can be non-reactive or reactive. A non-reactive quench gas can be delivered at a lower temperature than an ambient temperature of the reactant gas stream. The reactive quench gas can be selected from the group consisting of methanol, carbon dioxide, carbon monoxide, ammonia, nitrogen, a noble gas, hydrogen, a hydrocarbon gas, a silane gas. In embodiments, the system comprises a second quench gas. In embodiments, the system further comprises a solids collector in fluid communication with the annealing zone, wherein the organized carbon solids are segregated from the reactant gas stream. The solids collector can comprise a prefilter and a collection filter system.

The invention also includes methods for producing an isolated collection of organized hybrid carbon solids, comprising providing the system as described above. In some embodiments, the method comprises directing a feed gas comprising a hydrocarbon precursor and directing a plurality of nucleation seeds as a gaseous stream through the reaction chamber; exposing the gaseous stream to the energy input, thereby initiating chemical decomposition of the hydrocarbon precursor in the gaseous stream and forming initial reaction products; propagating the chemical decomposition within the gaseous stream, thereby converting a portion of the initial reaction products into carbon solids; depositing the carbon solids on the nucleation seeds within the gaseous stream, thereby producing the organized hybrid carbon solids; treating the gaseous stream with a quench gas to affect a physical or chemical property of the organized hybrid carbon solids; and separating the organized hybrid carbon solids from the gaseous stream to produce the isolated collection of organized hybrid carbon solids. In embodiments, the quench gas is a reactive quench gas that affects a chemical property of the organized hybrid carbon solids. The chemical property can be a surface chemical property of the organized hybrid carbon solids. In embodiments, the surface chemical property is altered by incorporating functional groups in the organized hybrid carbon solids. In embodiments, the surface chemical property is a hydrophobic or hydrophilic property.

Disclosed herein, in embodiments, are systems for forming organized carbon solids from a hydrocarbon precursor, comprising: a reaction chamber having an inlet end and an outlet end, wherein the reaction chamber comprises an initiation zone at the inlet end, a propagation zone distal to the initiation zone and in fluid communication with the initiation zone, and an annealing zone at the outlet end, distal to the propagation zone and in fluid communication with the propagation zone; wherein one or more conduits enter the initiation zone conveying a feed gas comprising the hydrocarbon precursor, and conveying a plurality of nucleation seeds; wherein the hydrocarbon precursor and the plurality of nucleation seeds are mixed before or during their entry into the initiation zone to form a feed gas mixture; wherein the feed gas mixture encounters an energy input in the initiation zone to form an activated gas stream comprising nucleation seeds and activated hydrocarbon species capable of undergoing chemical decomposition; wherein the activated gas stream enters the propagation zone and undergoes further chemical decomposition therein, forming a reactant gas stream comprising nucleation seeds and carbon solids, wherein the carbon solids deposit on the nucleation seeds to form organized carbon solids within the reactant stream; and wherein the reactant gas stream comprising the organized carbon solids enters the annealing zone, wherein a quench gas is delivered to affect a physical or chemical property of the organized carbon solids in the reactant gas stream. In embodiments, the hydrocarbon precursor is selected from the group consisting of ethylene, ethane, and acetylene. In embodiments, the feed gas mixture comprises a second hydrocarbon precursor that is different from the hydrocarbon precursor. In embodiments, the nucleation seeds comprise one or more inorganic materials, which inorganic materials can have magnetic or semiconductor properties. In embodiments, the nucleation seeds comprise silicon or silica. In embodiments, the energy input forms a plasma; in embodiments, energy input is derived from a chemical reaction. The quench gas can be non-reactive or reactive. A non-reactive quench gas can be delivered at a lower temperature than an ambient temperature of the reactant gas stream. The reactive quench gas can be selected from the group consisting of methanol, carbon dioxide, carbon monoxide, ammonia, nitrogen, a noble gas, hydrogen, a hydrocarbon gas, a silane gas. In embodiments, the system comprises a second quench gas. In embodiments, the system further comprises a solids collector in fluid communication with the annealing zone, wherein the organized carbon solids are segregated from the reactant gas stream. The solids collector can comprise a prefilter and a collection filter system.

Also described herein, in embodiments, are methods for producing an isolated collection of organized carbon solids, comprising providing the system as described above, directing a feed gas comprising a hydrocarbon precursor and directing a plurality of nucleation seeds as a gaseous stream through the reaction chamber; exposing the gaseous stream to the energy input, thereby initiating chemical decomposition of the hydrocarbon precursor in the gaseous stream and forming initial reaction products; propagating the chemical decomposition within the gaseous stream, thereby converting a portion of the initial reaction products into carbon solids; depositing the carbon solids on the nucleation seeds within the gaseous stream, thereby producing organized carbon solids; treating the gaseous stream with a quench gas to affect a physical or chemical property of the organized carbon solids; and separating the organized carbon solids from the gaseous stream to produce the isolated collection of organized carbon solids. In embodiments, the quench gas is a reactive quench gas that affects a chemical property of the organized carbon solids. The chemical property can be a surface chemical property of the organized carbon solids. In embodiments, the surface chemical property is altered by incorporating functional groups in the organized carbon solids. In embodiments, the surface chemical property is a hydrophobic or hydrophilic property.

### BRIEF DESCRIPTION OF FIGURES

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 depicts an embodiment of a reactor system for producing highly organized carbon solids.

FIG. 2 depicts an embodiment of a reactor system for producing highly organized carbon solids.

FIG. 3 depicts an embodiment of a reactor system for producing highly organized carbon solids.

### DETAILED DESCRIPTION

Disclosed herein are systems and methods for improved production of high-structure carbon black. These systems and methods involve two components: selection of feedstock for forming the carbon black, and seeding the reaction chamber to enhance surface-promoted deposition of high quality carbon black solids. In certain embodiments, the process is enhanced by introducing a quench gas having the ability to affect the final surface chemistry of the formed carbon black. Further disclosed herein are sample processes for improved production of high-structure carbon black.

### 1. Feedstock Selection

Currently, the main production method for carbon black is a furnace process that generates hot gas (1200-1800° C.) by combustion of natural gas or oil, with a saturated hydrocarbon feedstock being injected into the produced hot gas to undergo a complex set of reactions: thermal decomposition, particle nucleation, and particle growth and aggregation. Water is then injected into the reaction system to reduce the temperature of the carbon black stream leaving the decomposition reactor, thereby stopping the reactions. En route to forming carbon black, the saturated hydrocarbon feedstock converts into acetylene black and hydrogen: taking methane as a sample feedstock, acetylene and hydrogen are formed in a ratio of 1:3. Hydrogen, however, is known to hinder acetylene's reactivity, stopping the cascade of acetylene into higher-order condensates and solids. In fact, feeding additional hydrogen into a plasma reaction chamber arrests virtually all acetylene conversion into solids, so that only trace amounts of carbon solids accumulate on the walls of the chamber.

Starting with a saturated feedstock imposes a stoichiometric limitation on the production of solids. Using the example of methane, for every mol of acetylene that is produced, three mols of hydrogen are produced, with the hydrogen serving to prevent the further decomposition of acetylene into carbon solids. There is always too much hydrogen in the gas mixture if one begins with only saturated compounds as feedstock, suppressing nucleation and growth into primary particles that could subsequently cluster and interconnect. The consequence is that the rate of solid formation is extremely low. Not to be bound by theory, this mechanism can explain the low levels of carbon black formation that have plagued traditional processes.

The methods disclosed herein use unsaturated hydrocarbons as feedstock, thereby achieving a more favorable stoichiometry. Unsaturated volatile compounds can be used as feedstock, including but not limited to acetylene, ethylene, propene, butadiene and isoprene, and mixtures thereof. Because they are unsaturated, they release less hydrogen as they produce carbon solids, so that their conversion reactions are less influenced by the presence of hydrogen. In embodiments, ethylene is an advantageous main component for the feedstock gas stream, due to its favorable free energy change of decomposition. The methods disclosed herein can make use of the thermal decomposition properties of ethylene, acetylene, or other short-chain hydrocarbons (or combinations of the foregoing), to optimize this stage in the production of highly structured carbon black.

The Gibbs free energy of decomposition for two unsaturated feedstock sources, acetylene and ethylene, are set forth in Table 1 below, in comparison to the free energy of decomposition for two saturated molecules, methane and ethane.

TABLE 1

| | | |
|---|---|---|
| Methane | −50.8 | kJ/mol |
| Ethane | −32.9 | kJ/mol |
| Ethylene | 68.2 | kJ/mol |
| Acetylene | 209.2 | kJ/mol |

As shown in Table 1, methane and ethane have negative free energies, requiring energy input for decomposition. Ethylene and acetylene, by contrast, are exothermic, releasing free energy upon decomposition. These two materials (or combinations thereof) provide advantageous feed gases for the systems and methods disclosed herein. Moreover, once initiated, the conversion of ethylene and acetylene into solids is self-sustaining.

Ethylene, while still decomposing spontaneously as indicated by its exothermic free energy, does not convert into carbon solids as rapidly as acetylene, allowing more control over the process and the final product. In embodiments, ethylene can offer advantages as a main or supplemental feedstock for formation of highly structured carbon solids having superior electroconductivity performance, whereas the high energy content of acetylene can make it less advantageous as a primary feedstock for the processes described herein, as compared to ethylene. In traditional processes for forming carbon solids, acetylene feedstock converts to acetylene black by partial oxidation, a conversion that is rapid and self-sustaining because it is highly exothermic. However, the resulting carbon black thus formed from acetylene, termed acetylene black, falls short of the demanding specifications for high performance, high conductivity, as may be required by electronics applications such as battery electrodes. In embodiments, however, acetylene black, although less structured, can be useful for certain applications. For example, less structured carbon black can be used as an additive in rubber materials for tires. The feed gas composition used to form this type of less structured carbon black according to these systems and methods can be composed of one or more component gases, with the feed gas composition being engineered to attain the desired degree of structuring by varying the relative proportions of ethylene and acetylene. In embodiments, adding acetylene and ethane to the ethylene stream can be used, respectively, either to accelerate or decelerate the net decomposition. Acetylene decomposition will release more energy per mol than ethylene decomposition, so if the system is energy-poor this is a mechanism to add energy.

In embodiments, other gases can be added to the main feedstock to adjust the rate of decomposition and the structure of the resultant carbon black. For example, ethane decomposition can scavenge energy from the system and can therefore slow the net decomposition if there is excess energy. Using small amounts of added hydrogen (still maintaining low hydrogen-to-reactive-ingredient ratio) can further regulate in situ nucleation and particle growth, balancing and optimizing the overall rate of production, single-pass conversion, and final morphology complexity (i.e., dendritic inter-particle connectivity). In embodiments, selected self-catalytic and/or cross-linking-inducing compounds can be added to the gas feed to further enhance the quality of solid production and finetune the resulting dendritic architecture. In particular, certain aromatic compounds in trace amounts in the feed gas can further modulate product formation: exemplary feed additives include benzene (b.p., 80° C.), toluene (b.p., 111° C.), styrene (b.p., 145° C.), divinyl benzene (b.p., 195° C.), and naphthalene (b.p., 218° C.).

A key feature of these methods for forming highly-structured carbon black is its reliance on pure hydrocarbons as the main feed gas(es). Unlike conventional carbon black synthesis, there are no heteroatom impurities in the system and it can operate in an environment entirely or substantially free of oxygen, allowing the process to deliver ultra-high chemical purity and product quality. The carbon black and acetylene black formed through the methods disclosed herein are of exceptional purity, lacking the heteroatoms and polyaromatic hydrocarbons that are known to form on the surface of carbon black that is produced through traditional techniques such as pyrolysis.

### 2. Reaction Chamber Seeding

The systems and methods disclosed herein, as described above, use high-reactivity, unsaturated gases such as ethylene, acetylene, propylene, butadiene, isoprene, or mixtures thereof, as primary feedstock, thereby avoiding the stoichiometric limitations imposed by the presence of hydrogen in the reaction chamber where the carbon solids are being produced. In addition, these systems and methods seed the chamber wherein the feedstock decomposition takes place by with preformed nuclei (termed “nucleation seeds” or “nucleation seed particles”) intended to optimize conditions for the formation of highly structured carbon black. Without being bound by theory, it is believed that the addition of nucleation seed particles at the start of the decomposition reaction can remove variability in the reaction size, allowing the rate and structure of the resulting solid product to be more precisely controlled.

In embodiments, seeding the reaction chamber can be accomplished by spraying one or more types of nucleation seed particles, or “nucleation seeds,” into the chamber, wherein such nucleation seeds are dimensionally adapted for providing nucleation sites for structured carbon black formation. For nucleation seeds used in these systems and methods, any regular or irregular shape (whether spherical, cylindrical, plate-like, flake-like or any other geometric or random shape) is acceptable for use. In embodiments, the nucleation seeds can range in size from 10 nm to 100 nm in diameter; in other embodiments, the nucleation seeds can range in size up to one micron in diameter. In embodiments, the nucleation seeds can be configured as particles or fibers, or as nanoparticles or nanofibers. As used herein, the term nanoparticle refers to a particle substantially smaller than the size of a primary carbon black particle (nodule), which range from about 10 nm to about 100 nm in diameter, regardless of shape, including shapes that are spherical, cylindrical, plate-like, flake-like, or any other regular or irregular configuration. As used herein the term nanofiber refers to a nanoparticle configured as a fiber, where the term “fiber” refers to a structure having a large aspect ratio (i.e., a dimensional length much larger than its cross-sectional dimension, for example an aspect ratio that is larger than about 10, 20, 30, 50, or 100).

Advantageously, nucleation seeds can be used in accordance with these systems and methods to allow deposition of highly structured pure carbon on a core material that does not comprise elemental carbon, thereby forming hybrid particles: as used herein, the term “hybrid particle” refers to a particle having a core-shell structure that becomes organized within a highly structured architecture of carbon solids, in which the particle's shell is formed from elemental carbon, and the particle's core comprises materials that are non-elemental-carbon materials. While the primary material for the hybrid particle core excludes elemental carbon, it is understood that there can be additional materials in the hybrid particle core besides the primary material, and such additional materials can include elemental carbon as well as other substances distinct from elemental carbon. Such hybrid particle cores having two distinct component substances are termed heterogeneous, meaning that they include a non-elemental-carbon primary material and one or more other distinct materials, which can include or exclude elemental carbon.

Primary materials suitable for forming nucleation seeds can be organic substances or inorganic substances or combinations thereof, whether natural or synthetic. In more detail, in certain embodiments heterogeneous nucleation seeds can include one or more inorganic or organic materials as components, but they do not contain allotropes of elemental carbon. In other embodiments, heterogeneous nucleation seeds can include two or more different materials, in which at least one component material (the primary material) is an inorganic material or an organic material that is not an allotrope of elemental carbon; in such embodiments, additional materials that are allotropes of elemental carbon can be incorporated into the heterogeneous nucleation seed, so long as the elemental carbon materials do not cover, coat, or otherwise envelop the primary (non-elemental-carbon) material. Nucleation seeds can be formed from a single material, or can be heterogenous, formed as mixtures, composites, lattices or layers, amalgams, or other combinations of dissimilar materials, provided that any heterogeneous nucleation seed includes a non-elemental-carbon material that is not itself coated with elemental carbon. In a heterogeneous nucleation seed, a primary non-elemental-carbon substance can be present alongside or in juxtaposition to an elemental carbon material, but the elemental carbon cannot envelop the non-elemental-carbon substance so that the elemental carbon material forms a surface or a covering of the non-elemental-carbon substance. Whether homogeneous or heterogeneous, the nucleation seeds provide the core for the formation of hybrid particles.

Since the surface (the shell) of these hybrid primary particles is carbon, the particles aggregate and agglomerate as if they were pure carbon particles, forming interconnected, highly branched, high surface-area-per-volume dendritic networks with desirable conductive properties. However, since the core of the hybrid primary particles comprises materials distinct from elemental carbon, the resulting highly structured carbon solids display unique performance attributes unavailable in pure carbon systems.

Nucleation seeds suitable for these purposes can comprise natural or synthetic inorganic materials such as precious metals, magnetic materials, semiconductor materials, silicon, silica, and the like. Nucleation seeds suitable for these purposes can comprise natural or synthetic natural organic materials (i.e., compounds or polymers containing carbon-hydrogen bonds, with or without heteroatoms) such as simple organic compounds, plastics, rubbers, and biomaterials, with such organic materials excluding elemental carbon. Nucleation seeds can further include chemicals that are reactive with the nucleation seed material itself or that are applied to the surface of the material, for example to functionalize the material or facilitate its attachment to the elemental carbon that forms the shell of the hybrid particles. The composition and architecture of a nucleation seed can be engineered so that the hybrid particles comprising the nucleation seed form structurally-designed carbon solids having preselected properties. Once the nucleation seed composition and architecture is determined, such nucleation seeds can be introduced into the reaction chamber system described herein to form nuclei for the deposition of the carbon solids, thereby yielding hybrid particles that become organized into highly structured forms.

In an embodiment, a hybrid particle can be formed from a precious metal nucleation seed: these hybrid particles can be formed by seeding the reaction chamber with gold, silver or platinum nanoparticles. Growth of graphitic overcoats on precious metal nucleation seeds can be followed by inter-particle bridging to form highly branched (i.e., dendritic) networks, thereby yielding ultra-high conductivity solids using the systems and methods disclosed herein. In embodiments, the precious metal cores are capable of injecting or storing electrons to and from the carbon outer shell when a certain threshold voltage is imposed, delivering amplification of conductivity that can be externally triggered and controlled.

In an embodiment, a hybrid particle can be formed from a magnetic nucleation seed, understood to comprise a material that can be manipulated using magnetic fields: these hybrid particles can be formed by seeding the reaction chamber with a metallic substance such as iron, nickel, or cobalt. Suitable magnetic substances can include metals and non-metals. Metallic magnetic nucleation seeds can comprise magnetic metals, magnetic oxides, and the like, with or without additional layers or coatings. In embodiments, a magnetic substance can be made a non-metal, for example from an organic polymer such as emeraldine base polyaniline and tetracyanoquinodimethane. The magnetic nucleation seed can further include other materials, whether magnetic or non-magnetic. In embodiments, such materials can be further treated with other chemicals to provide functionalization. Magnetic nucleation seeds provide nuclei for the deposition/growth of the conductive carbon layer on the nuclei, using the systems and methods disclosed herein.

The presence of the conductive carbon on the surface of the magnetic nucleation seeds combines with the magnetic properties of the nucleation seeds themselves to impart advantageous properties to the finally formed carbon solids. As an example, a dendritic network of hybrid particles comprising magnetic nucleation seeds can have its conductivity tuned by an externally imposed magnetic field. For example, discharging of batteries or super-capacitors formed from magnetic hybrid particles can occur while the network is in its “relaxed” isotropic state, while charging can be done rapidly with an externally imposed magnetic field to temporarily align/distort the network to enhance directional conductivity. As used herein, the term directional conductivity as used herein refers to the measured conductivity of the system as a function of the relative orientation of the externally imposed magnetic field. In embodiments, a dendritic network of hybrid particles comprising magnetic nucleation seeds can be used to detect the presence and strength of a magnetic field by monitoring its electrical conductivity.

In an embodiment, a hybrid particle can be formed from a semiconductor nucleation seed; these hybrid particles can be formed by seeding the reaction chamber with a semiconductor material. A semiconductor material is understood to be a material having an electrical conductivity value falling between that of a conductor such as metallic copper, and an insulator such as fused glass. Insulators, such as fused quartz and glass, have very low conductivities, on the order of 10⁻¹⁸ to 10⁻¹⁰ siemens per cm; and conductors, such as aluminum, have high conductivities, typically from 10⁴ to 10⁶ siemens per cm. The conductivities of semiconductors are between these extremes and are generally sensitive to temperature, illumination, magnetic fields, and minute amounts of impurity atoms. Semiconductor materials can include, without limitation, pure elements such as silicon or germanium, or compounds such as gallium arsenide or cadmium selenide. Semiconductor materials useful as nucleation seeds can further be processed by doping, i.e., the addition of minute quantities of other elements into the intrinsic semiconductor material to affect the material's conductivity.

Overcoating the semiconductor nucleation seeds with carbon solids as described herein creates hybrid primary particles, which in turn aggregate and agglomerate to form highly branched dendritic networks using the systems and methods disclosed herein. Such networks can exhibit unique characteristics of voltage-dependent conductivity, with numerous potential applications. Doping semiconductor materials such as silicon and gallium arsenide prior to carbon shell deposition can further vary the voltage dependent conductivity. Composite materials containing such hybrid particles can serve as gating or switching devices.

In an embodiment, a hybrid particle can be formed from a silicon core, without reference to potential semiconductor properties; these hybrid particles can be formed by seeding the reaction chamber with a silicon material in accordance with the systems and methods disclosed herein. Optionally, a silicon nucleation seed can be treated with a silane coupling agent such as phenylpropyl silane to facilitate the affixation of the elemental carbon solids thereto. Networks comprising hybrid particles having silicon as their cores can also be tailored for applications where conductivity is desirable. Hybrid particles comprising graphitic-shell-covered silicon nucleation seeds can be engineered to provide both high capacity and intrinsic electrode conductivity, via the systems and methods disclosed herein that produce highly-structured conductive network morphology.

One potential use of such materials is for forming battery anodes for lithium batteries. Currently, graphite is used for these purposes, but is limited by its low lithium loading capacity. Silicon provides a good alternative, having a loading capacity about ten times greater than graphite, but it is fragile: with charging-discharging cycles, the silicon lattice expands and contracts, which ultimately can lead to fracturing of the silicon crystal. Hybrid seeds having silicon nucleation seeds as cores can offer both the capacity of silicon and the necessary flexibility to withstand the expansion and contraction that accompanies charging and discharging. A dendritic network formed from such particles is capable of deforming, thus supporting repeated stress-strain from charging-discharging cycles without losing graphitic shell-shell contact, and thus retaining conductivity and capacity. These properties, the combination of good capacity and good conductivity, can allow the materials made from silicon-core hybrid particles to be used in batteries, for example as anodes for lithium batteries.

In an embodiment, a hybrid particle can be formed from a silica or silicate nucleation seed; these hybrid particles can be formed by seeding the reaction chamber with a silica or silicate material. Optionally, a silica or silicate nucleation seed can be treated with a silane coupling agent such as phenylpropyl silane to facilitate the affixation of the elemental carbon solids thereto, or to facilitate the attachment of other chemical compounds having advantageous properties. Hybrid particles formed from silica or silicate nucleation seeds can, in embodiments, be engineered to form dendritic networks using the systems and methods disclosed herein.

Networks comprising hybrid particles having silica or silicate as their cores can be tailored for applications where conductivity is not an important feature, for example for use in making tire rubber. While silica additives are familiar to artisans in the field of tire manufacture, such additives have limitations. Using silica as a component of the core for hybrid particles can retain a rigid glass backbone for the tire additive material, thus preserving attributes such as reduced rolling friction and improved wear that are imparted to tires by plain silica additives. The flexible and precise dendritic network morphology control allows optimization of tire performance properties. In addition, the silica-based hybrid particles will provide ultraviolet protection to the tires via their black pigmentation. Such particles lend themselves to strong binding with the tire rubber matrix and straightforward dispersion within the matrix, just like traditional carbon black fillers.

In embodiments, particles suitable as nucleation seeds (whether particles or nanoparticles) can be configured as fibers or nanofibers (as applicable), which can be formed as natural or synthetic fibers. As used herein, the term “natural” as a modifier for the terms fibers or nanofibers refers to a fiber or a nanofiber derived from a natural source without artificial modification. Natural fibers include vegetable-derived fibers, animal-derived fibers and mineral-derived fibers. Vegetable-derived fibers can be predominately cellulosic, e.g., cotton, jute, flax, hemp, sisal, ramie, and the like. Vegetable-derived fibers can include fibers derived from seeds or seed cases, such as cotton or kapok, or fibers derived from leaves, such as sisal and agave, or fibers derived from the skin or bast surrounding the stem of a plant, such as flax, jute, kenaf, hemp, ramie, rattan, soybean fibers, vine fibers, jute, kenaf, industrial hemp, ramic, rattan, soybean fiber, and banana fibers, or derived from the fruit of a plant, such as coconut fibers, or derived from the stalk of a plant, such as wheat, rice, barley, bamboo, and grass. Vegetable-derived fibers can include wood fibers or wood pulp fibers. Animal-derived fibers typically comprise proteins, e.g., wool, silk, mohair, and the like. Mineral-derived natural fibers are obtained from minerals. Mineral-derived fibers can be derived from asbestos. Mineral-derived fibers can be a glass or ceramic fiber, e.g., glass wool fibers, quartz fibers, aluminum oxide, silicon carbide, boron carbide, and the like. As used herein, the term “synthetic fibers” include fibers that are manufactured in whole or in part. Synthetic fibers include artificial fibers, where a natural precursor material is modified to form a fiber. For example, cellulose (derived from natural materials) can be formed into an artificial fiber such as Rayon® or Lyocell®. Cellulose can also be modified to produce cellulose acetate fibers. These artificial fibers are examples of synthetic fibers. Synthetic fibers can be formed from synthetic materials that are inorganic or organic. Synthetic inorganic fibers include mineral-based fibers such as glass fibers and metallic fibers. Glass fibers include fiberglass and various optical fibers. Metallic fibers can be deposited from brittle metals like nickel, aluminum or iron, or can be drawn or extruded from ductile metals like copper and precious metals. Synthetic organic fibers for use as nucleation seeds include polymeric fibers. Examples of polymeric fibers suitable for these purposes include fibers made from polyamide nylon, PET or PBT polyester, polyesters, phenol-formaldehyde (PF), polyvinyl alcohol, polyvinyl chloride, polyolefins, acrylics, aromatics, polyurethanes, elastomers, and the like. A synthetic fiber can be formed from more than one natural or synthetic fiber. For example, a synthetic fiber can be a coextruded fiber, with two or more polymers forming the fiber coaxially or collinearly. While nucleation seeds can comprise elemental carbon fibers or nanofibers as a component of the nucleation seed structure, such elemental carbon fibers can be included only in the presence of a primary seed material that does not comprise elemental carbon.

In accordance with the systems and methods set forth herein, growth from a seed to a primary particle increases mass by a million times. In other words, one gram of these seed particles yields one ton of product. This degree of amplification makes the processes disclosed herein extremely economical. The nucleation provided by the hybrid seed particles in the decomposition reactor facilitates the rapid adhesion of decomposition products from the feed gas, efficiently growing highly-structured carbon solids at tremendous speed. By seeding with numerous nuclei, the condensation reaction rate (i.e., growth of nuclei) can be greatly accelerated without having to resort to intense energy input, allowing modulation of the reaction and control the product quality at the same time. Moreover, dispensing a precisely metered ratio of selected seed particles into the reaction chamber (e.g., by spraying, injection other dispensation techniques) can offer fine control of the degree of branching of the resulting morphology.

### 3. Exemplary Processes

a. Energy Inputs and Energy Sources

By employing feed gas(es) comprising unsaturated hydrocarbon gases and by introducing nucleation seeds into the feed gas(es) stream, reactions to form highly structured carbon black solids can be accomplished by a variety of energy inputs. In embodiments, plasma generation can be used to produce the appropriate reactions, with plasma being formed by input from various energy sources, such as microwaves, radiofrequency, or dielectric barrier discharge. In other embodiments, triggered chemical reactions can act as sources for the energy input, for example oxidation via trace oxygen; such reactions do not involve plasma formation. Choice of an energy source is influenced by the free energy change underlying the conversion of the selected unsaturated hydrocarbon into carbon black. For example, the reaction that degrades ethylene into carbon black is exothermic, and the function of the energy source is only to overcome the initial activation energy, i.e., to trigger the initial breakdown, anticipating that there is enough energy released to trigger neighboring ethylene molecules to decompose into carbon black in a chain reaction. With other feed gases, more energy input can be required.

Two exemplary embodiments of the reaction process are described below in more detail.

b. Batch Processes

A batch process for producing highly structured carbon black can be performed in a pressurizable vessel containing the desired mixture of the unsaturated hydrocarbon feed gas, for example ethylene, in combination with hydrogen, and/or other hydrocarbon gases at a desired pressure. For the fixed-volume chamber, the pressure will dictate the density of each species and thus will allow fine control of the rate of reaction (for example, ethylene degradation). In this process, hydrogen and other hydrocarbons can be used to regulate the rate of the reaction, recognizing that hydrogen tends to slow the production of carbon from hydrocarbon species, and other hydrocarbons can act as reactants along with the primary feed gas. Varying the components of the gas mixture provides the ability to speed up or slow down the overall rate of carbon production from the hydrocarbon sources. In embodiments, acetylene can be used as an auxiliary hydrocarbon reactant along with ethylene as the primary hydrocarbon reactant, with acetylene accelerating the overall hydrocarbon-to-carbon reaction. Saturated hydrocarbons added to the source gas mixture will tend to slow the overall hydrocarbon-to-carbon reaction. Source gases within the pressurized vessel can be suspended and mixed by agitation, for example with a propeller or other agitation mechanism.

With the gas mix in the vessel at the appropriate pressure to provide the preselected density of each gas species, ignition of the mixture can be performed, for example using a spark gap, where a high voltage can be applied across two closely-positioned electrodes so that a spark arcs. With arc formation, a current flows between the electrodes, with the current being supported by the gas molecules between the electrodes. The high voltage ionizes the gas within the arc, and the current flowing within the arc heats the entrained gas to high temperature, thereby setting off the decomposition reaction for the feed gas(es); ethylene, for example, decomposes at a temperature of about 730° C. at 1 atm pressure. The energy input can either result in an oxidation reaction (as may be seen in internal combustion engines, for example) or it can trigger the ethylene itself to decompose, a process that can take place in the absence of oxygen, or it can proceed in the presence of a small amount of oxygen. Once triggered, the ethylene decomposition reaction can propagate throughout the chamber. As used herein, the term “decomposition reaction” refers to a chemical decomposition, i.e., a process whereby a more complex molecule such as ethylene is broken down into smaller molecular fragments. For a hydrocarbon molecule, the chemical decomposition can ultimately yield hydrogen molecules and elemental carbon, although there can be numerous intermediate species formed in addition to elemental carbon and hydrogen. The intermediate species formed during a decomposition reaction can include charged species such as ions or radicals, which can combine to form more complex reaction products. For example, reaction products such as diacetylene, vinylacetylene, benzene, polyaromatic hydrocarbons, and other hydrocarbon species can be formed, which are potentially susceptible to further chemical transformation or chemical decomposition. These energized intermediate species can be termed “activated hydrocarbon species,” which are energized hydrocarbon fragments whose energy levels render them capable of engaging in further chemical reactions, whether to combine to form more complex reaction products, or to decompose further, yielding smaller molecular fragments and/or elemental carbon or hydrogen molecules. It is understood that the activated hydrocarbon species, for example those derived from ethylene or other unsaturated hydrocarbons, can undergo sufficient chemical decomposition that they produce elemental carbon that can be organized into primary carbon black particles which can be further organized into highly structured carbon black using the systems and methods disclosed herein. The presence of the suspended seed particles provide nuclei for the formation of primary carbon black particles, with their subsequent organization into highly structured carbon black.

Following the decomposition reaction, the reaction chamber can be evacuated with a pump and the carbon black solids can be retrieved. Solids retrieval can be conducted using techniques familiar to skilled artisans, depending on the locus of the formed solids. For example, solids coating the walls of the reaction chamber as a fine dust can be retrieved by scraping the solids off the walls. In cases where the solids can be suspended in a gas flow passing out of the chamber, the solids can be collected by a filter, for example a bag filter, although many filter options are available, as understood by skilled artisans in the field. In embodiments, the solids are evacuated from the chamber at the end of the reaction cycle, passing into a filter or collection mechanism downstream from and separate from the reaction chamber. Using this arrangement, the solids can be retrieved from the collection mechanism while the reaction chamber is being filled and recharged for another reaction cycle, thus improving the overall efficiency of the batch process. To prepare the decomposition reactor for another batch conversion, the chamber can be backfilled with nitrogen gas, other inert gas, or by regular atmospheric air. In embodiments, a plurality of reaction chambers can be arranged in series, so that their reaction cycles and recharging cycles are synchronized. A multichambered system can allow increased efficiency by multiplexing chambers each carrying out a batch process.

c. Continuous Processes

Similar to a batch process, a continuous process for forming highly-structured carbon solids involves (i) a preselected mixture of source gases, including a primary feed gas, and optional hydrogen and/or auxiliary feed gases in specified ratios, and (ii) seed particles for nucleation introduced into the gas mixture. For the continuous process, all of these species are being introduced continuously. In embodiments, ratios of ethylene to acetylene can be selected for optimum product formation, with desirable ranges from about 1% acetylene and about 99% ethylene to about 99% acetylene and about 1% ethylene.

Energy input for a continuous system can take many forms. In embodiments, a small spark gap arc can be produced, which will trigger the decomposition of the feed gases to for the carbon solids. In embodiments, plasma can be ignited and sustained sufficiently to produce the decomposition reaction through energy sources such as microwaves, radiofrequency (RF), and dielectric barrier discharge (DBD). In embodiments, a plasma can be created in the input gas mixture by mechanisms familiar to skilled artisans such as by direct irradiation with microwaves, or with an induction coupling scheme such as in RF plasmas, or by capacity coupling as in DBD.

In these cases, the reaction chamber can be configured as a cylinder, with the feed gas(es) and suspended nuclei flowing or swirling through the cylindrical reaction tube having a proximal end and a distal end. Flow of the feed gases is arranged unidirectionally, from proximal to distal, avoiding back flow of the feed gas for safety purposes. For example, using ethylene as the main feed gas, flow or pressure adjustments can prevent back flow, for example using low pressure and/or fast flow rate, to avoid the tendency of ethylene to decompose under high pressure and temperature.

The composition of the feed gases can influence the amount and duration of energy input. For example, since ethylene decomposition is exothermic, continuous energy input, for example via a sustained plasma, is unnecessary; in fact, a sustained plasma can be counterproductive if it prevents the carbon atoms derived from ethylene decomposition from recombining to form carbon black on the nuclei particles. Without being bound by theory, it is understood that, if mixed with the proper hydrocarbons, the ethylene gas decomposition is self-sustaining. Therefore, a decomposition reaction for ethylene gas should proceed spontaneously once the reaction begins, without the need to apply addition input energy.

In an embodiment, a main feed gas such as ethylene can be excited to decompose by bombarding it with another auxiliary stream of excited atoms. In an embodiment, hydrogen gas can be used to provide the excited atoms, which are created by energizing hydrogen to form a low pressure plasma with excited hydrogen atoms having greater than 2 eV energy, using one of the known techniques for plasma formation. For example, hydrogen gas can pass through a multichannel screen, wherein each channel is configured as a small DBD plasma generator. As another example, hydrogen gas can be irradiated by microwaves to for excited hydrogen atoms. However it is produced, the excited hydrogen atoms (H*) can be directed to flow into the main feed gas stream, imparting enough energy to the feed gas molecules to decompose. Because the decomposition of ethylene into carbon solids is exothermic, this gas is especially advantageous for use with an auxiliary stream of excited atoms such as the plasma-energized hydrogen.

In other embodiments, a main feed gas such as ethylene can be excited to decompose by a known plasma initiation process such as microwave, spark discharge, or dielectric barrier breakdown. In other embodiments, a main feed gas such as ethylene can be excited to decompose by an oxidation combustion reaction. In such an embodiment, feed gas(es) constantly flow through the decomposition reactor, but a small amount of oxygen is admitted to permit combustion. The combustion provides sufficient heat to trigger decomposition in the feed gas(es), with the heat of decomposition propagating three-dimensionally both antegrade and retrograde. The velocity of the net gas flow is managed so that the ethylene continues to decompose in a self-sustaining way, for example by constricting the flow within the decomposition reactor or increasing the pressure, with settings selected to optimize the amount and direction of ethylene decomposition within the reaction chamber

For a continuous process, the addition of seed particles to the gas mixture can be dispensed and metered appropriately, so that the particles entering the reaction chamber are available to provide nuclei for the decomposing feed gas(es) as they form carbon solids. Collection of carbon solids can be continuous as well, with product collection carried out by techniques familiar to skilled artisans. For example, solids can be collected with a cyclone filter or a bag reverse air/pulse jet filter. The latter is a bag filter in which the bag can be mechanically agitated and the captured product is expelled through the entry opening. The expelling is performed by a puff of air that is pressurized in the opposite to normal flow direction. In an exemplary reverse air/pulse jet filter, the exit port with the filter can be positioned laterally or located at the top of a chamber. Gas flows and blows the suspended solids into the filter at the exit. When the flow is cut momentarily there is a back pressurized puff that blows from the exit back into the chamber. This causes the solid particles on the filter to fly off, to be collected at the base. Variations on this technology and other suitable filter mechanisms would be familiar to those having ordinary skill in the art.

d. Reactor Configurations

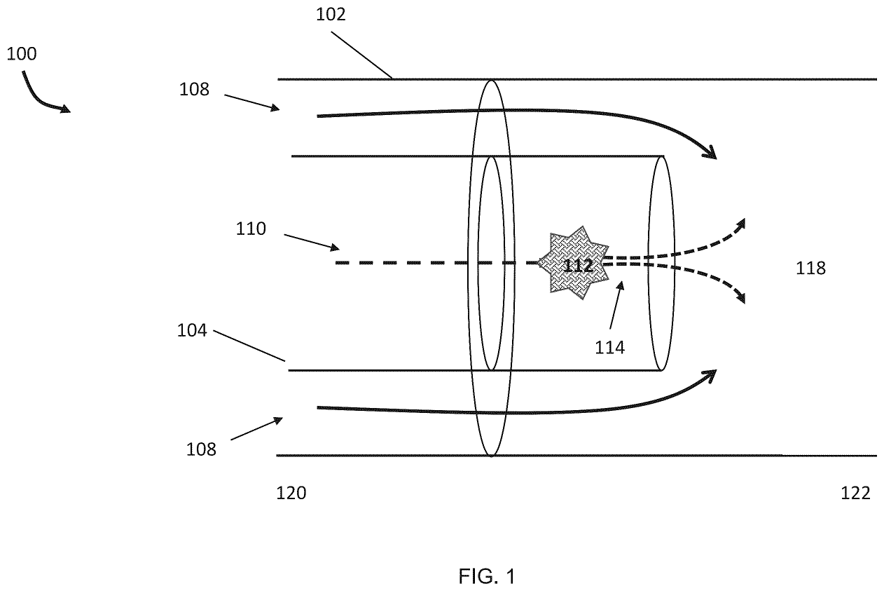

An exemplary reactor system for continuous production of carbon solids is shown in FIG. 1. One geometry that would allow this is a coaxial setup, for example consisting of two concentric tubes, an inner one with a smaller diameter and an outer one with a larger diameter. Inside the inner tube is hydrogen gas. The hydrogen gas can be excited by inductive coupling, for example a coil winding around the tube. To achieve this, radio frequency (RF) power can be delivered to the coil which establishes an oscillating magnetic field inside the tube and thereby excites the hydrogen. An alternative embodiment involves a dielectric breakdown barrier (DBD) plasma technique. In either of these arrangements, the hydrogen gas is isolated when it is excited. Within the outer tube, ethylene, and other hydrocarbons flow from a proximal (inflow) end to a distal (outflow) end, with a variety of flow patterns available. In embodiments, mixing of the component feed gases can be accentuated by directing these gases in swirling patterns or by creating patterns of turbulent flow. In other embodiments, laminar flow patterns can be produced in the outer cylinder.

As shown in FIG. 1, a reactor system 100 includes an outer cylinder 102 and an inner cylinder 104 in a coaxial arrangement. In the depicted embodiment, the outer cylinder 102 contains feed gas(es) 108, which are conveyed from an inlet (proximal) end 120 towards an outflow (distal) end 122, while the inner cylinder directs an inflow of an excitable gas such as hydrogen 110 towards an activation area 112 where the excitable gas is excited by an energy source such as a plasma, to produce a stream of excited atoms, for example excited hydrogen atoms 114 as shown in this Figure. The excited hydrogen atoms 114 then flow out of the inner cylinder 104 into a mixing region 118, where they are mixed with the feed gas(es) 108 flowing in the outer cylinder towards the outflow end 122. In the depicted embodiment, the outer cylinder 102 is longer than the inner cylinder 104, allowing the feed gas(es) 108 to bypass the activation area 112 where the excitable gas inflow 110 is being excited by an energy source, and further allowing the excited atoms such as excited hydrogen atoms 114 to merge with the feed gas(es) 108 in the mixing region 118.

The feed gas feed 108 can comprise a single feed gas, for example, ethylene, or a mixed stream with a plurality of feed gases, such as ethylene and acetylene. As previously described, other hydrocarbon and non-hydrocarbon cases can be added to the feed gas stream to optimize its reaction properties. In embodiments, the gases in the feed gas stream are premixed and flow through the entire system as a mixed stream. In other embodiments, one or more of the component gases is introduced separately from the others, or in separate mixtures with different compositions of gases, with all component gases ultimately mixed in the outer cylinder 108 as they flow through towards the mixing region 118. Gas flow composition and mixing arrangements can be selected so that the feed gas composition and its flow patterns promote the formation of the highly structured carbon solids. Nucleation seeds (not shown) can be introduced into one of the component gas flows, or into the mixed gas flow stream, or both, so that the nucleation seeds are suspended in the gas flow that is present in the mixing region 118 when the feed gas(es) encounter the excited hydrogen atoms 114.

In embodiments, a microwave-induced plasma can be used to energize the excitable gas 110 flowing through the activation area 112, wherein energy from a focused microwave beam ignites and sustains a plasma. Using the reactor configuration depicted in FIG. 1, the microwave beam can be focused into the center of the inner cylinder 104 where the excitable gas such as hydrogen gas 110 is flowing, thereby allowing the feed gas(es) 108 (for example, a gas flow comprising ethylene) to pass through the outer cylinder 102 unaffected by the microwaves passing through it. In other embodiments, other energy sources can be used to ignite and sustain such a plasma. For use with microwaves as an energy source to create a plasma, the inner and outer cylinder are transparent to microwaves, so that the energy passes through the cylinder walls efficiently.

Using DBD as the energy source for a reactor as shown in FIG. 1, a coaxial electrode can be deployed within the inner cylinder 104 containing the excitable gas such as hydrogen 110 so that a plasma is formed and retained within the activation area 112. In embodiments using RF as the energy source for the activation area 112 as depicted in FIG. 1, the inner cylinder 104 can be wrapped with a coil of wire that is energized by RF, which creates heat in the copper coil and thus heats the excitable gas such as hydrogen 110 within the inner cylinder 104 via inductive coupling.

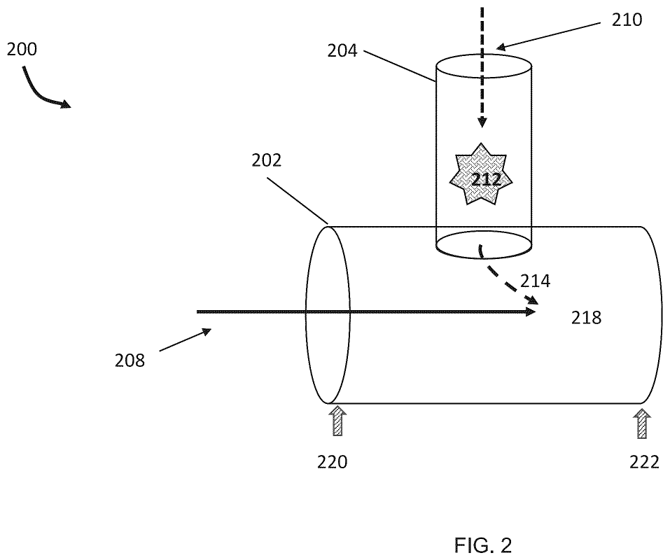

Other arrangements can be envisioned whereby an excitable gas is energized to produce energized atoms that are directed to contact the feed gas(es) in order to produce the desired reactions. An alternate embodiment of a reactor design employing these principles is depicted in FIG. 2. As shown in this Figure, a reactor system 200 includes a feed gas conduit 202 and an excited gas conduit 204, with the excited gas conduit 204 intersecting the feed gas conduit 202 at an angle. The feed gas conduit 202 contains feed gas(es) 208 that flow from an inflow (proximal) end 220 to an outflow (distal) end 222. While the depicted embodiment depicts the feed gas(es) 208 as a single stream, it is understood that this stream of feed gas(es) 208 can comprise one or more feed gases, which can be premixed, or which can enter the feed gas conduit 202 in separate gas streams (not shown), to be mixed therein. Nucleation seeds (not shown) can be introduced into one of the component gas flows, or into the mixed gas flow, or both, so that the nucleation seeds are present in the mixing region 218 when the feed gas(es) encounter the excited atoms 214.

The excited gas conduit 204 directs an inflow of an excitable gas such as hydrogen 210 towards an activation area 212, where the excitable gas atoms (e.g., hydrogen atoms) are excited by an energy source such as a plasma. The excited atoms 214 then flow out of the excited gas conduit 204 into a mixing region 218, where they are mixed with the feed gas(es) 208 flowing in the feed gas conduit 202. While the excited gas conduit 204 is shown to intersect the feed gas conduit 202 at a 90-degree angle in the depicted embodiment, it is understood that the angle of intersection can be varied, with an angle selected to optimize the interaction of the excited gas atoms 214 and the feed gas(es) 208.

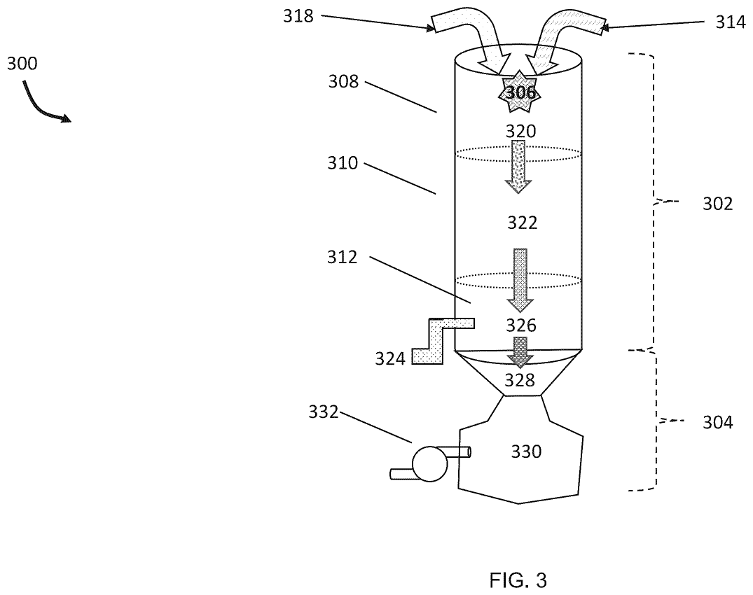

FIG. 3 provides a schematic design for a system for forming highly structured carbon solids. FIG. 3 depicts an embodiment of a reactor system 300 that includes a reaction chamber 302 and a solids collector 304. The reaction chamber 302 includes an initiation zone 308, a propagation zone 310, and an annealing zone 312. Pressure differentials and gas flow rates can be engineered between or among the zones, so that gas stream flows from one chamber to the next throughout the decomposition process, without propagating retrograde.

Hydrocarbon feed gas(es) 314 enter the initiation zone 308, along with a plurality of nucleation seeds 318, each shown in the depicted embodiment entering the initiation zone 308 through its own conduit. The nucleation seeds 318 can all be the same in material composition, size, etc., or they can be different, with properties selected for their advantageous effects on the system's processes or products. In other embodiments, the nucleation seeds 318 and the feed gas(es) 314 can enter through a single conduit within which they are mixed, or through different conduits. If multiple nucleation seeds 318 are used, they can be mixed together or dispensed separately into the initiation zone 308 through one or more conduits, in any desirable arrangement. Similarly, the feed gas(es) 314, if different, can be mixed together or dispensed separately into the initiation zone 308; a single feed gas can enter the initiation zone 308 through one conduit or through a plurality of conduits, with or without nucleation seeds 318 admixed therein.

Within the initiation zone 308, the feed gas(es) 314 and nucleation seeds 318 are mixed, and the mixture encounters an energy source 306 that initiates the chemical decomposition of the feed gas, for example by spark or by plasma formation, to form the activated gas stream 320. In other embodiments (not shown) feed gases and nucleation seeds can be mixed before entering the initiation zone, and can enter the initiation zone as a single stream through a single conduit, with the nucleation seeds entrained in the flowing feed gas; this mixture then enters the initiation zone where it encounters the energy source that initiates the chemical decomposition of the feed gas.

Hydrocarbon feed gas(es) can include various species such as ethylene, ethane, and acetylene, that decompose at different rates due to their different Gibbs free energy values. Some species exhibit endothermic decompositions and others are exothermic: by using a mixture of endothermic and exothermic species, the overall rate of decomposition can be tuned to optimize the growth of carbon black on the nucleation seeds 318. It is understood that dendritic growth of carbon solids on the seeds is determined in part by the rate of decomposition and the type of nucleation seeds that are provided. In an embodiment, the feed gas(es) can include oxygen, so that the energy source 306 can be a spark that ignites it. In other embodiments, a plasma can be initiated via the energy source 306, using microwave power, RF coupling, dielectric barrier breakdown, or other mechanisms familiar in the art.

Following the initiation of the decomposition, the activated feed gas stream 320 containing the entrained nucleation seeds passes into a propagation zone 310, wherein the decomposition reaction progresses, with the resultant carbon solids becoming deposited on the nucleation sites provided by the nucleation seeds. The gas stream in the propagation zone contains carbon solids organized on the nucleation seeds and residual hydrocarbon reaction products, forming a reactant gas stream 322 that passes into the annealing zone 312.

In the depicted embodiment, the reactant gas stream 322 encounters one or more quench gases 324 in the annealing zone 312, where the one or more quench gases 324 affect the reactions within the reactant gas stream 322, forming a quenched gas stream 326 as described below in more detail.

Quench gases can be non-reactive or reactive. A non-reactive quench gas does not react chemically with the reactant gas stream 322 or the carbon solids organized on the nucleation seeds that are entrained in the reactant gas stream 322. Thus the effect of the non-reactive quench gas can be selected so that it affects a physical property of the reactant gas stream 322. As an example, a non-reactive quench gas can be added at a lower temperature than the ambient temperature of the reactant gas stream 322, thereby lowering the temperature of the gases and solids in the stream, and thus affecting the rate of formation of the organized carbon solids or their architecture. In other embodiments, the quench gas 324 can be reactive, having the ability to interact with the reactant gas stream 322 or with the carbon solids organized on the nucleation seeds that are entrained therein to alter the chemical composition of the carbon solids organized on the nucleation seeds. Selection of an appropriate quench gas can introduce functional groups onto the surfaces of the organized carbon solids, thereby affecting their surface chemical properties. As examples, the quench gas can be methanol, carbon dioxide, carbon monoxide, ammonia, nitrogen, a noble gas, hydrogen, a hydrocarbon gas, a silane gas, a mixture thereof, or other species or mixtures capable of affecting the chemical properties of the quenched gas stream. In embodiments, a reactive quench gas can affect both the physical and the chemical properties of the quenched gas stream, for example by decreasing its temperature as well as affecting its chemical composition.

In an embodiment, the quench gas 324 serves to arrest the further growth of the carbon black particles. The quench gas 324 can be used to arrest the growth of the carbon black particles by choice of the quench gas species or mixture. The introduction of the quench gas 324 into the system can also influence the rate of carbon black particle growth or stop it entirely. In an embodiment, a quench gas 324 can be selected that scavenges energy from the ongoing decomposition reaction, thereby slowing or stopping further chemical reactions and preventing further carbon accumulation on the nucleation seeds in the reactant gas stream 322. In another embodiment, a quench gas 324 can be at a lower temperature than the reactant gas stream 322, so that the encounter between the cooler quench gas 324 and the hotter reactant gas stream 322, slows the chemical reactions, thereby preventing further carbon accumulation on the nucleation seeds. While altering a physical property of the reactant gas stream by lowering its temperature, the quench gas 324 also affects the rate of chemical reactions proceeding in the reactant gas stream, ultimately affecting the architecture of the carbon on the nucleation seeds.

In embodiments, the quench gas 324 directly affects a chemical property of the organized carbon solids, for example by altering the surface chemistry of the carbon black particles. For example, if hydrogen gas is introduced as a quench gas 324, the hydrogen atoms can bind to the surface of the carbon black particles. As another example, if carbon dioxide is introduced as a quench gas 324, it can anneal and favorably bind the carbon black agglomerates. As yet another example, quench gases such as ammonia gas, sulfur dioxide, silane gas, carbon monoxide, and methanol (among others) can be used to functionalize the surface of the carbon black particles, thus preparing them for use in other applications, by adding functional groups such as amine groups, sulfur groups, silicon-containing groups, or ether groups to the surface. As used herein, the term “functional group” refers to specific groupings of atoms within molecules that have their own characteristic chemical properties, regardless of the other atoms present in the molecule, such as alcohols, amines, carboxylic acids, ketones, ethers, and the like. Functional groups can add specific reactivity to the carbon black particles, or they can affect the hydrophobicity or hydrophilicity of the particles. Without being bound by theory, it is understood that altering the hydrophobicity or hydrophilicity of the carbon black particles by adding functional groups to their surfaces can facilitate the use of such functionalized carbon black particles in other applications where their hydrophobic or hydrophilic properties would be advantageous.

In embodiments, multiple quench gases (not shown) can be introduced, either as gas mixtures, or as separate gas inflows within the annealing zone 312. Multiple quench gases can be selected having different properties. For example, a gas can be used to arrest further growth of the carbon black particles, and another gas can be used to introduce functional groups on the carbon black particles; in embodiments, the same gas can be used for both functions: as an example, a single quench gas can both cool and alter surface chemistry. In embodiments, the quench gas can be introduced into the annealing zone at two locations and at different temperatures. In embodiments, the same gas can be used for both functions if that quench gas is introduced into the annealing zone at the same location.

This quenched gas stream 326 passes into the solids collector 304 containing mechanisms for removing the particulate solids from the quenched gas stream 326. In the depicted embodiment, the quenched gas stream 326 enters the collector 304, where it is processed through a prefilter 328 for separating particulate solids, such as a cyclone collector. In the depicted embodiment, the carbon solids segregated by the prefilter 328 are collected in a filter collection system 330, for example a collection filter bag. In the depicted embodiment, a pump 324 can provide air flow through the filter collection system 330 to facilitate solids collection. Other arrangements for segregating the carbon solids from the quenched gas stream 326 and for collecting this material can be envisioned by practitioners of ordinary skill in the art. For example, multiple collection filter bags can be used, allowing each to be emptied sequentially while filtration proceeds in the others. As another example, the large collection filter bag 330 can be in fluid communication with multiple smaller filters that collect the particulate solids. In embodiments, a pump 324 or similar apparatus can be used to create pressure differentials that propel the quenched gas stream 326 through the collector 304.

While this invention has been particularly shown and described with references to preferred embodiments thereof, it will be understood by those skilled in the art that various changes in form and details may be made therein without departing from the scope of the invention encompassed by the appended claims.

1. A system for forming organized hybrid carbon solids from a hydrocarbon precursor, wherein the hybrid carbon solid comprises a core-shell structure in which the shell is formed from elemental carbon, and the core comprises materials that are non-elemental-carbon materials, the system comprising:
a reaction chamber having an inlet end and an outlet end,
wherein the reaction chamber comprises an initiation zone at the inlet end, a propagation zone distal to the initiation zone and in fluid communication with the initiation zone, and an annealing zone at the outlet end, distal to the propagation zone and in fluid communication with the propagation zone;
wherein one or more conduits enter the initiation zone conveying a feed gas comprising the hydrocarbon precursor, and conveying a plurality of nucleation seeds, wherein the nucleation seeds comprise one or more inorganic materials;
wherein the hydrocarbon precursor and the plurality of nucleation seeds are mixed before or during their entry into the initiation zone to form a feed gas mixture;
wherein the feed gas mixture encounters an energy input in the initiation zone to form an activated gas stream comprising nucleation seeds and activated hydrocarbon species capable of undergoing chemical decomposition;
wherein the activated gas stream enters the propagation zone and undergoes further chemical decomposition therein, forming a reactant gas stream comprising nucleation seeds and carbon solids, wherein the carbon solids deposit on the nucleation seeds to form the organized hybrid carbon solids within the reactant stream; and
wherein the reactant gas stream comprising the organized hybrid carbon solids enters the annealing zone, wherein a quench gas is delivered to affect a physical or chemical property of the organized hybrid carbon solids in the reactant gas stream.

2. The system of claim 1, wherein the hydrocarbon precursor is selected from the group consisting of ethylene, ethane, and acetylene.

3. The system of claim 1, wherein the feed gas mixture comprises a second hydrocarbon precursor that is different from the hydrocarbon precursor.

4. The system of claim 1, wherein the nucleation seeds comprise one or more organic materials.

5. The system of claim 1, wherein the inorganic materials have magnetic or semiconductor properties.

6. The system of claim 1, wherein the nucleation seeds comprise silicon or silica.

7. The system of claim 1, wherein the energy input forms a plasma.

8. The system of claim 1, wherein the energy input is derived from a chemical reaction.

9. The system of claim 1, wherein the quench gas is non-reactive.

10. The system of claim 9, wherein the quench gas is delivered at a lower temperature than an ambient temperature of the reactant gas stream.

11. The system of claim 1, wherein the quench gas is reactive.

12. The system of claim 11, wherein the quench gas is selected from the group consisting of methanol, carbon dioxide, carbon monoxide, ammonia, nitrogen, a noble gas, hydrogen, a hydrocarbon gas, a silane gas.

13. The system of claim 1, comprising a second quench gas.

14. The system of claim 1, further comprising a solids collector in fluid communication with the annealing zone, wherein the organized hybrid carbon solids are segregated from the reactant gas stream.

15. The system of claim 14, wherein the solids collector comprises a prefilter and a collection filter system.

16. A method for producing an isolated collection of organized hybrid carbon solids, comprising:
providing the system of claim 1;
directing a feed gas comprising a hydrocarbon precursor and directing a plurality of nucleation seeds as a gaseous stream through the reaction chamber;
exposing the gaseous stream to the energy input, thereby initiating chemical decomposition of the hydrocarbon precursor in the gaseous stream and forming initial reaction products;
propagating the chemical decomposition within the gaseous stream, thereby converting a portion of the initial reaction products into carbon solids;
depositing the carbon solids on the nucleation seeds within the gaseous stream, thereby producing the organized carbon solids;
treating the gaseous stream with a quench gas to affect a physical or chemical property of the organized hybrid carbon solids; and
separating the organized hybrid carbon solids from the gaseous stream to produce the isolated collection of organized hybrid carbon solids.

17. The method of claim 16, wherein the quench gas is a reactive quench gas that affects a chemical property of the organized hybrid carbon solids.

18. The method of claim 17, wherein the chemical property is a surface chemical property of the hybrid carbon solids.

19. The method of claim 18, wherein the surface chemical property is altered by incorporating functional groups in the organized hybrid carbon solids.

20. The method of claim 18, wherein the surface chemical property is a hydrophobic or hydrophilic property.
